(19) United States
(12) Patent Application Publication
(10) Pub. No.: US 2023/0209724 A1
(43) Pub. Date: Jun. 29, 2023

(54) CONDUCTOR BONDING METHOD

(71) Applicant: Seong Ryong AN, Seoul (KR)

(72) Inventor: Seong Ryong AN, Seoul (KR)

(21) Appl. No.: 17/924,949

(22) PCT Filed: Jun. 5, 2020
(86) PCT No.: PCT/KR2020/007319

§ 371 Date: Nov. 11, 2022

(30) Foreign Application Priority Data
May 12, 2020 (KR) 10-2020-0056539

(51) Int. Cl. H05K 3/32; H05K 3/10

(52) U.S. Cl. CPC H05K 3/323; H05K 3/103; H05K 2201/0338; H05K 2201/10128; H05K 2203/166

(57) ABSTRACT

Provided is a conductor bonding method capable of simply and easily performing a conductor bonding operation by placing conductive particle patterns and a conductive particle fixing material directly on lead terminals of an electronic device, the conductor bonding method includes 1) placing a first conductive particle fixing material 110 on lead terminals 2 of a display panel 1 (S100), 2) forming conductive particle patterns by placing conductive particles 120 in a dense state only on regions, in an upper surface of the first conductive particle fixing material 110, corresponding to the regions where the lead terminals 2 are formed in the display panel 1 (S200), 3) aligning a conductor 3 on the lead terminals 2 of the display panel 1, on which the first conductive particle fixing material and the conductive particle patterns are formed in step 1) and step 2) (S100-S200) (S300), and 4) bonding the aligned conductor 3 to the lead terminals 2 by applying heat or pressure (S400).

### CROSS REFERENCE TO RELATED APPLICATIONS

This application is a National Stage of International Application No. PCT/KR2020/007319 filed on Jun. 5, 2020, claiming priority based on Korean Patent Application No. 10-2020-0056539 filed on May 12, 2020.

### TECHNICAL FIELD

The present disclosure relates to a conductor bonding method, and more particularly, to a conductor bonding method capable of easily and simply performing a bonding operation of a conductor by placing conductive particle patterns and a conductive particle fixing material directly on lead terminals of an electronic device.

### RELATED ART

In a display apparatus such as a liquid crystal display (LCD), etc., a driving circuit IC that supplies a voltage to an electric field forming device of each pixel via a signal line has to be mounted around an LCD panel in order to adjust an electric field in each pixel in the apparatus. A driving IC mounting technology, which is a technical method for electrically connecting the liquid crystal panel to the driving IC, is required to have a fine pitch connection, easy connection process, and high reliability according to demands for complicated driving IC, increase in the number of pixels, and high resolution. In order to satisfy the demands for such a driving IC mounting technology, a COG technology of performing a facedown bonding of a bump of the driving IC to an electrode of a liquid crystal panel, for example, an ITO electrode, has been developed.

Although various COG technologies are being introduced by each company, the most common method is a method of thermally attaching and pressing a driving IC having a bump by using an anisotropic conductive film (ACF) and mounting the driving IC on a liquid crystal panel substrate. The anisotropic conductive film has been developed for the past several decades, and the anisotropic conductive film has a structure in which conductive particles are uniformly dispersed mainly in a thermosetting epoxy resin.

As the conductive particles, a polymer or glass ball coated with gold, silver, nickel, or metal of a diameter of about 5 to 20 µm is usually used. Depending on an amount of conductive particles, a polymer matrix having inherently non-conductive property has anisotropic conductive properties (in the case of 5 to 10 vol%) or isotropic conductive properties (in the case of 25 to 35 vol%).

As the number of pixels increases, the number of bumps of a driving IC increases, and a pitch interval between the bumps becomes very narrow as shown in FIG. 1. When the pitch interval and the width of the bumps themselves are reduced as described above, an electric short occurs when conductive particles 12 between the bumps are placed between adjacent patterns. Due to the above technical issues, solutions are concentrated on arranging of conductive particles per unit area to minimize electrical resistance in the pattern while maintaining a certain interval between the conductive particles.

Therefore, in an ACF 10 according to the related art, dispersing of the conductive particles 12 for maintaining constant intervals has been significantly considered while reducing sizes of the conductive particles 12. However, the above direction of developing technology has faced a technical limitation.

In addition, a light-emitting diode (LED) may be used widely in various wavelength bands from ultraviolet ray band to infrared ray band. Since Nichia commercialized nitride light emitting diodes (GaN LEDs), owing to the continuous development in semiconductor thin film technology, process technology, and device technology, GaN-LED has brought a dramatic improvement in performance and reliability, and demands for LEDs have been increasing explosively with the launch of high-luminance and high-power output application products such as mobile phones, TVs, lightings, electronic signs, traffic signs, vehicles, home appliances, etc. from small display devices.

In particular, as a luminous efficiency increased rapidly after year 2005, a huge market of LCD backlight units in the display industry was generated, and it is expected to steadily increase the distribution and development of the LED lights until year 2030 because excellence in energy saving has been proved and price lowering would be accelerated in the lighting industry.

Recently, results of many researches and developments that utilize a degree of freedom in size adjustment, a flexible characteristic, and an effect of selective light-emitting wavelength of the LEDs have been published. LEDs used for lighting mainly have a size of 1000 µm × 1000 µm. When an area of the LED is reduced to 1/100 times or less, the size becomes 100 µm × 100 µm that is about a thickness of a human hair, and an LED having a size less than the above is referred to as a micro LED. The micro LED may be mounted on a stretchable substrate, a flexible substrate, and a three-dimensional substrate, and thus may be applied to various fields such as wearable displays, lighting, skin-attached medical devices, semiconductor equipment, autonomous driving sensors, light sources for big data services, etc.

In the micro LED, as the size of an entire micro LED device is reduced to 15 µm × 30 µm, the size of one electrode is reduced to 10 µm × 15 µm or less. Even in the micro LED having the above size, each electrode has to be connected to an electrode pattern formed on a substrate and receive supply of an electric current in order to emit light. Here, the electrodes are electrically connected to the electrode pattern generally by using an ACF.

However, as shown in FIG. 2, conductive particles 12 in the ACF 10 according to the related art are uniformly arranged at regular intervals. Here, because each conductive particle 12 has a diameter of about 3 µm, in a region corresponding to an electrode having a size of 10 µm × 15 µm, five or less conductive particles may be arranged considering sizes and intervals of the conductive particles 12, as shown in FIG. 2. Assuming that the electrodes are connected by about five conductive particles, a ratio of the area wherein the conductive particles are arranged with respect to a total electrode area is 30% or less.

When the electrode and the electrode pattern are connected by such a small number of conductive particles, heat, etc. is generated due to excessive resistance in the process of light emission, and thus, an electric short may occur or a device may be dead.

In addition, in a bonding method using the ACF according to the related art, the bonding process is carried out while supplying the ACF during the bonding process, processing equipment is complicated and an accuracy in the processes degrades.

### DETAILED DESCRIPTION OF THE DISCLOSURE

### Technical Problem

The present disclosure provides a conductor bonding method by which a conductor bonding operation is simply and easily carried out because conductive particle patterns and a conductive particle fixing material are provided directly on a lead terminal of an electronic device.

### Technical Solution

A conductor bonding method according to the present disclosure includes 1) placing a first conductive particle fixing material 110 on lead terminals 2 of a display panel 1 (S100), 2) forming conductive particle patterns by placing conductive particles 120 in a dense state only on regions, in an upper surface of the first conductive particle fixing material 110, corresponding to the regions where the lead terminals 2 are formed in the display panel 1 (S200), 3) aligning a conductor 3 on the lead terminals 2 of the display panel 1, on which the first conductive particle fixing material and the conductive particle patterns are formed in step 1) and step 2) (S100-S200) (S300), and 4) bonding the aligned conductor 3 to the lead terminals 2 by applying heat or pressure (S400).

The conductor bonding method may further include, after performing step 2) (S200), placing a second conductive particle fixing material 130 that fixes the conductive particle patterns, on the conductive particle pattern (S500).

Each of the first conductive particle fixing material 110 and the second conductive particle fixing material 130 may be one selected from a non-conductive film, a non-conductive tape, and a non-conductive liquid.

Meanwhile, in the embodiment, the conductive particles 120 may have a particle diameter of 10 µm or less and may include metal particles or polymer particles plated with metal.

Also, in the present disclosure, a protective film 140 may be further coated on the second conductive particle fixing material 130 or the conductive particle pattern, and before performing step 3) (S300), isolating of the protective film may be further performed.

### Advantageous Effects of Disclosure

According to a conductor bonding method of the present disclosure, conductive particles are intensively arranged only in lead terminal patterns and are not arranged in the other regions. Thus, the electric connection may be stably made within the lead terminal patterns, and the electric short generation is fundamentally prevented due to the regions where the conductive particles are not arranged.

In addition, because the conductive particles are fixed and arranged on the lead terminals in the same pattern as that of the lead terminals, the conductor may be accurately and easily bonded through a simple process without additionally supplying a film such as an anisotropic conductive film (ACF), etc.

### BRIEF DESCRIPTION OF THE DRAWINGS

FIGS. 1 and 2 are diagrams showing arrangement state of conductive particles in an anisotropic conductive film (ACF) according to the related art.

FIGS. 3 and 4 are diagrams showing processes of a first step (S100) in a conductor bonding method according to the present disclosure.

FIGS. 5 and 6 are diagrams showing processes of a second step (S200) in a conductor bonding method according to the present disclosure.

FIG. 7 is a diagram showing processes of a third step (S300) in a conductor bonding method according to the present disclosure.

FIG. 8 is a diagram showing a process in which a protective film is further coated in the third step (S300) of the conductor bonding method according to the present disclosure.

FIG. 9 is a diagram showing a process in which a protective film is isolated in the third step (S300) of the conductor bonding method according to the present disclosure.

FIG. 10 is a diagram showing processes of a fourth step (S400) in a conductor bonding method according to the present disclosure.

FIGS. 11 and 12 are partially cross-sectional views showing a structure in a bonded state.

FIG. 13 is a plan view showing a lead terminal and a conductor structure in a bonded state.

FIG. 14 is a flowchart illustrating a conductor bonding method according to the present disclosure.

FIGS. 15 and 16 are diagrams showing arrangement states of conductive particles in an ACF according to an embodiment of the present disclosure.

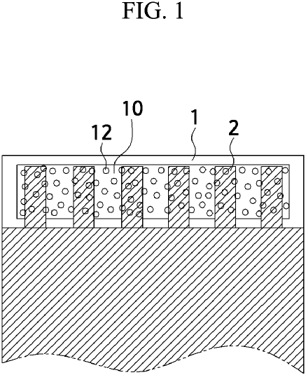

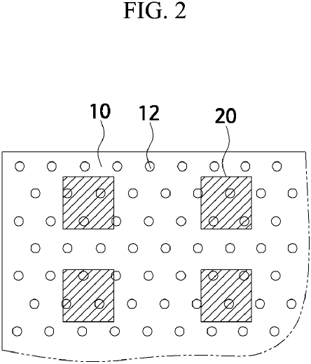

### BEST MODE

Provided is a conductor bonding method capable of simply and easily performing a conductor bonding operation by placing conductive particle patterns and a conductive particle fixing material directly on lead terminals of an electronic device, the conductor bonding method includes 1) placing a first conductive particle fixing material 110 on lead terminals 2 of a display panel 1 (S100), 2) forming conductive particle patterns by placing conductive particles 120 in a dense state only on regions, in an upper surface of the first conductive particle fixing material 110, corresponding to the regions where the lead terminals 2 are formed in the display panel 1 (S200), 3) aligning a conductor 3 on the lead terminals 2 of the display panel 1, on which the first conductive particle fixing material and the conductive particle patterns are formed in step 1) and step 2) (S100-S200) (S300), and 4) bonding the aligned conductor 3 to the lead terminals 2 by applying heat or pressure (S400).

### MODE

Hereinafter, one or more embodiments will be described in detail with reference to accompanying drawings.

### <Embodiment 1>

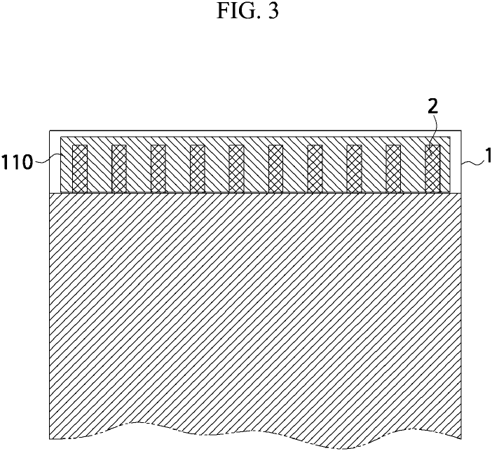

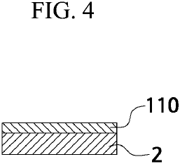

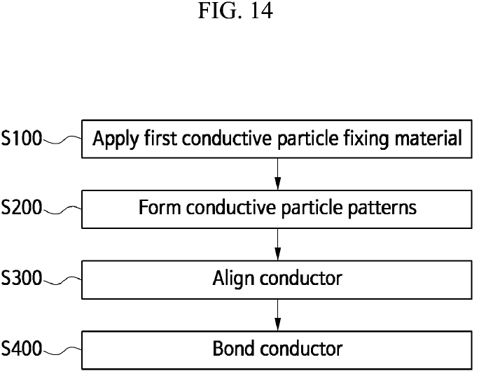

In the embodiment, the electronic device may include various electronic devices such as a display apparatus, a display panel, etc. A conductor bonding method according to the embodiment starts with step S100 in which a first conductive particle fixing material is placed, as shown in FIG. 14. In detail, in this operation (S100), as shown in FIGS. 3 and 4, a first conductive particle fixing material 110 is thinly placed on lead terminals 2 of a display panel 1. The first conductive particle fixing material 110 includes a material that may attach and fix first conductive particles 120 that will be described later on the lead terminals 2. For example, the first conductive particle fixing material 110 may include one selected from a non-conductive film, a non-conductive tape, and a non-conductive liquid.

In the embodiment, the first conductive particle fixing material 110 may be placed in a manner of entirely covering the plurality of lead terminals 2 or in a manner of separately covering each of the lead terminals 2, as shown in FIG. 3.

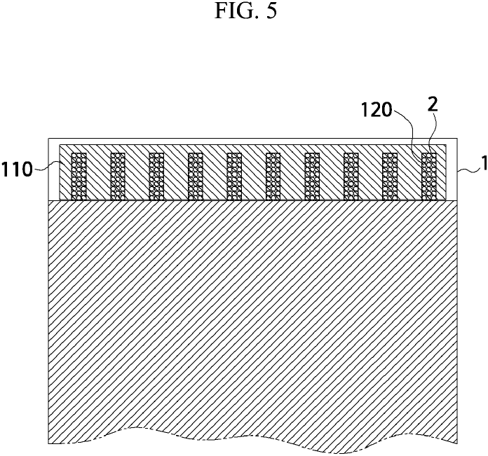

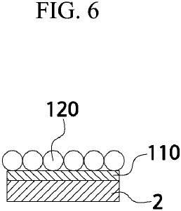

Next, as shown in FIG. 14, an operation of forming a conductive particle pattern (S200) is performed. In this operation (S200), as specifically shown in FIGS. 5 and 6, on an upper surface of the first conductive particle fixing material 110, the conductive particles 120 are placed only on regions corresponding to the regions, where the lead terminals 2 of the electronic device are formed, to be dense to form the conductive particle pattern. That is, the conductive particle pattern is formed by arranging the conductive particles 120 in a dense state to be a pattern matching the shape of the lead terminals 2.

In addition, in the embodiment, ‘arranged in a dense state’ denotes that the conductive particles 120 are arranged while coming into contact with one another without forming a separation space or while being as close to one another as possible. Therefore, in the conductive particle pattern according to the embodiment, the conductive particles may be arranged without having an empty space other than a gap that is inevitably formed when the conductive particles are in close contact with or adjacent to one another.

In detail, a ratio of an area in which the conductive particles are arranged with respect to a total area of one conductive particle pattern according to the embodiment is 60% or greater.

* Ratio of conductive particle arrangement (%) = area of conductive particle arrangement/entire pattern area × 100

When the ratio of the conductive area is high as 60% or greater, in a next operation of bonding a conductor 3 (S400), a large number of conductive particles 120 are arranged between the conductor 3 and the lead terminal 2, and the possibility of generating a connection failure is lowered. In addition, even in use after the bonding process, electric energization is carried out over a large area, and then, resistance is reduced and the possibility of generating defects such as heat generation during operation may be reduced. Meanwhile, the conductor 3 may include a conductor on an FPCB.

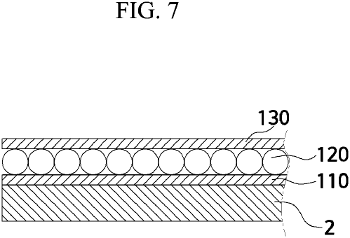

In addition, in the embodiment, as shown in FIG. 7, an operation of placing a second conductive particle fixing material 130 that fixes the conductive particle pattern on the conductive particles (S500) may be further performed after the process of forming the conductive particle pattern (S200).

When the conductor alignment process (S300) and the bonding process (S400) are immediately performed after the conductive particle pattern forming process (S200), the process of placing the second conductive particle fixing material 130 may not be necessary. However, when the electronic device is stored and the conductor alignment process (S300) and the bonding process (S400) are performed or is moved to another space and the conductor alignment process (S300) and the bonding process (S400) are performed after a considerable time amount has passed since the conductive particle pattern is formed, the second conductive particle fixing material 130 is placed once more for protecting and fixing the conductive particle pattern.

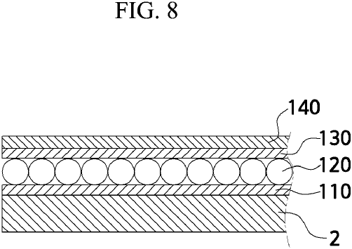

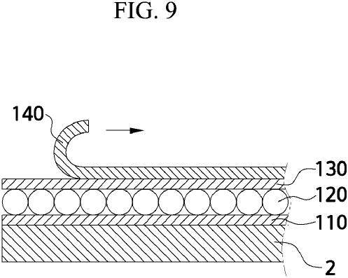

Moreover, as shown in FIG. 8, a protective film 140 may be further coated on the second conductive particle fixing material 130 or the conductive particle pattern, and the protective film 140 is isolated and removed before performing the conductor alignment process (S300) as shown in FIG. 9. Therefore, when the protective film 140 is coated, a protective film isolation process may be further performed before the conductor alignment process (S300).

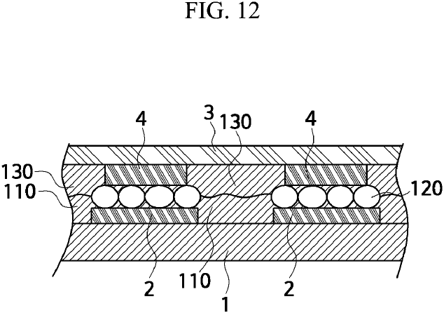

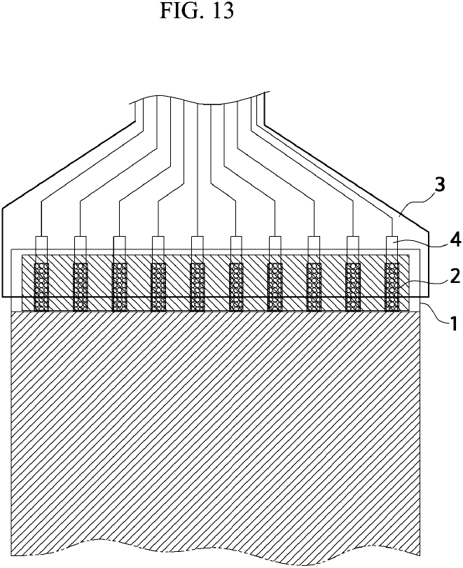

Next, as shown in FIG. 14, the process of aligning the conductor 3 on the lead terminals 2 of the display panel 1, on which the first conductive particle fixing material 110 and the conductive particles 120 are formed is performed (S300). In this process S300, as shown in FIG. 12 in detail, positions of conductor patterns 4 having the same interval as that of the patterns of the lead terminals 2 and the conductive particle patterns are adjusted so that each interval between the conductor patterns 4 coincides with that of the patterns of the lead terminals 2 or the conductive particle patterns.

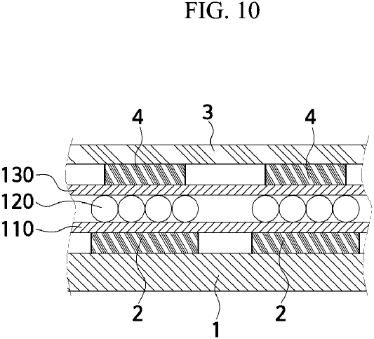

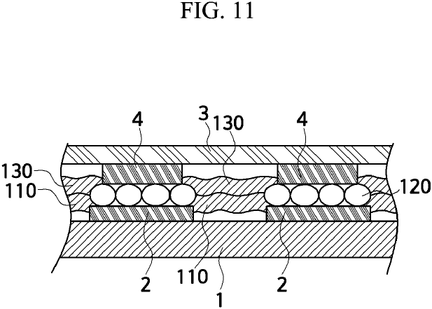

Next, as shown in FIG. 14, the operation of bonding the aligned conductor 3 onto the lead terminals 2 by applying heat or pressure is performed (S400). That is, as shown in FIGS. 10 and 11, the bonding is carried out in the manner of applying both the heat and pressure from upper and lower sides or applying one of the heat and pressure while the conductor patterns 4 and the lead terminals 2 are in close contact with each other. When the bonding is performed as described above, as shown in FIG. 11, the conductive particles 120 between the conductor patterns 4 and the lead terminals 2 allow the both to be electrically connected while coming into contact with the conductor patterns 4 and the lead terminals 2. Here, the conductive particles 120 are slightly pushed and deformed into elliptical shapes, and the first and second conductive particle fixing materials 110 and 120 are pushed to opposite sides to fill empty spaces.

### <Embodiment 2>

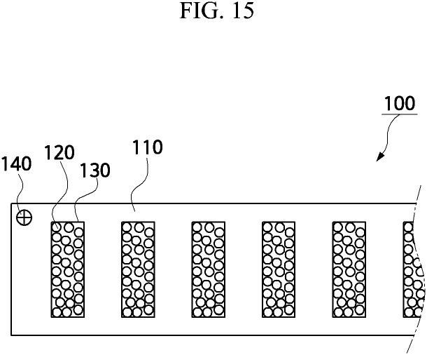

An anisotropic conductive sheet 1000 according to the embodiment has a sheet shape as a whole and includes a sheet 1100 and the conductive particles 1200, as shown in FIG. 15. The sheet 1100 forms the overall exterior of the anisotropic conductive sheet 1000 according to the embodiment and includes a plastic resin. The sheet 1100 may be formed of a thermosetting epoxy resin or other resins.

The sheet is virtually divided into an area in which the conductive particles 1200 are arranged and an area in which the conductive particles 1200 are not arranged. Here, the area in which the conductive particles 1200 are arranged may be referred to as a conductive pattern 1300, and the other area may be referred to as a non-conductive pattern. In addition, the conductive pattern 1300 may be changed into various shapes, and the shape and size of the conductive pattern 1300 may be precisely the same as those of the electrode pattern formed on the substrate, on which the anisotropic conductive sheet 1000 is to be mounted.

In the conductive pattern 1300 set as above, the plurality of conductive particles 1200 are arranged in close contact with one another as shown in FIG. 15. Here, ‘arranged in close contact with one another’ denotes that the conductive particles 1200 are densely arranged while contacting each other without having a separation space. Therefore, in the anisotropic conductive sheet 1000 according to the embodiment, the conductive particles may be arranged without forming an empty space, other than a gap that is inevitably formed while the conductive particles are in close contact with one another, in the conductive pattern 1300.

In detail, in the anisotropic conductive sheet 1000 according to the embodiment, a ratio of an area in which the conductive particles are arranged with respect to the entire area in one conductive pattern may be 60% or greater.

$$\begin{matrix}\text{* Ration of conductive particle arrangement (\%) = area of conductive particle} \\ \text{arrangement/entire pattern area} \times \text{100}\end{matrix}$$

When the conductive area ratio is high as 60% or greater, a large number of conductive particles 1200 are arranged between the electrode and the electrode pattern in the process of mounting electrodes and electrode patterns, and thus, a possibility of generating the connection failure may decrease. In addition, even in use after the mounting operation, the electricity is energized over a large area, and thus, the resistance is lowered and the possibility of generating defects such as heat generation during operation also decrease.

In addition, in the anisotropic conductive sheet 1000 according to the embodiment, the conductive particles 1200 may be only arranged in the virtual conductive pattern 1300, but some may be arranged out of the conductive pattern 1300.

Meanwhile, in the embodiment, the conductive particles 1200 may have a particle diameter of 10 µm or less and may include metal particles or polymer particles plated with metal.

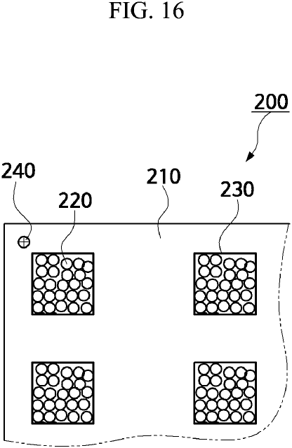

In addition, the anisotropic conductive sheet 1000 and 2000 according to the embodiment may further include a mark 1400 and 2400 as shown in FIGS. 15 and 16. The anisotropic conductive sheet 1000 and 2000 according to the embodiment includes the conductive patterns having the same shapes and sizes as those of the electrode patterns formed on the substrate on which the mounting operation is to be performed, and thus, the anisotropic conductive sheet 1000 and 2000 has to be accurately aligned with the substrate in the actual mounting operation.

Therefore, the mark 1400 and 2400 is indicated at an edge or corner of the sheet 1100 and 2100 to be used as a reference point in the aligning operation with the substrate.

### INDUSTRIAL APPLICABILITY

According to the anisotropic conductive sheet of the present disclosure, the conductive particles are intensively arranged only in certain patterns and are not arranged in the other regions. Thus, the electric connection may be stably made within the certain patterns, and the electric short generation is fundamentally prevented due to the regions where the conductive particles are not arranged.

In particular, because the conductive particles are intensively arranged in the certain patterns according to the present disclosure, the occurrence of electric short may be prevented by utilizing the regions where the conductive particles are not arranged, without reducing the size of the conductive particles. Thus, handling of the conductive particles becomes easy during the manufacturing process of the anisotropic conductive sheet.

1. A conductor bonding method comprising:
1) placing a first conductive particle fixing material 110 on lead terminals 2 of a display panel 1 (S100);
2) forming conductive particle patterns by placing conductive particles 120 in a dense state only on regions, in an upper surface of the first conductive particle fixing material 110, corresponding to the regions where the lead terminals 2 are formed in the display panel 1 (S200);
3) aligning a conductor 3 on the lead terminals 2 of the display panel 1, on which the first conductive particle fixing material and the conductive particle patterns are formed in step 1) and step 2) (S100-S200) (S300); and
4) bonding the aligned conductor 3 to the lead terminals 2 by applying heat or pressure (S400).

2. The conductor bonding method of claim 1, further comprising, after performing step 2) (S200),
placing a second conductive particle fixing material 130 that fixes the conductive particle patterns, on the conductive particle pattern (S500).

3. The conductor bonding method of claim 2, wherein each of the first conductive particle fixing material 110 and the second conductive particle fixing material 130 is one selected from a non-conductive film, a non-conductive tape, and a non-conductive liquid.

4. The conductor bonding method of claim 1, wherein the conductive particles 120 each have a diameter of 10 µm or less and include metal particles or polymer particles plated with metal.

5. The conductor bonding method of claim 2, wherein a protective film 140 is further coated on the second conductive particle fixing material 130 or the conductive particle pattern, and before performing step 3) (S300), isolating of the protective film is further performed.
